(19) United States
(12) Patent Application Publication
(10) Pub. No.: US 2011/0084711 A1
(43) Pub. Date: Apr. 14, 2011

(54) CAPACITANCE SENSING CIRCUIT WITH ANTI-ELECTROMAGNETIC INTERFERENCE CAPABILITY

(75) Inventors: YU-CHENG CHANG, HSINCHU COUNTY (TW); CHUNG-YUAN CHEN, HSINCHU COUNTY (TW)

(73) Assignee: SITRONIX TECHNOLOGY CORP., HSINCHU COUNTY (TW)

(21) Appl. No.: 12/900,622

(22) Filed: Oct. 8, 2010

(30) Foreign Application Priority Data
Oct. 8, 2009 (TW) 098134063

(51) Int. Cl. G01R 27/26

(52) U.S. Cl. 324/684

(57) ABSTRACT

The present invention relates to a capacitance sensing circuit with anti-EMI capability. A filter is coupled to a capacitor under test; receives a plurality of reference signals; and produces a first filter signal and a second filter signal. A difference circuit receives the first and second filter signals; eliminates the common-mode noise in the first and second filter signals; and produces a difference signal. The amplitude of the difference signal is related to the capacitance value of the capacitor under test. Thereby, the purpose of sensing capacitance can be achieved. In addition, by eliminating common-mode noise using the difference circuit, the anti-EMI capability can be achieved. Because the difference circuit can adjust the dynamic range of the output of the filter, the capacitance sensing circuit with anti-EMI capability can achieve capacitance sensing in few clock cycles.

### FIELD OF THE INVENTION

The present invention relates generally to a capacitance sensing circuit, and particularly to a capacitance sensing circuit with anti-electromagnetic interference (EMI) capability.

### BACKGROUND OF THE INVENTION

The applications of capacitance sensing and detection are increasingly wide spreading owing to the development of modern computer technologies, for example, fingerprint identification, microelectromechanical accelerometers, and capacitive touch panels. The capacitance sensing and detection technology according to the prior art generally adopts the capacitance-to-frequency conversion circuit. FIG. 1 shows a block diagram of a capacitance sensing apparatus according to the prior art. As shown in the figure, a first comparator 100′, a second comparator 102′, a control circuit 104′, and a resistor 106′ form an oscillation circuit, which is coupled to a capacitor under test 108′. Different capacitance values will result in different oscillation frequencies. By detecting the oscillation frequency, the capacitance value of the capacitor under test 108′ is deduced, and hence achieving the objective of sensing capacitance.

FIG. 2 shows a block diagram of another capacitance sensing apparatus according to the prior art. As shown in the figure, a constant current source 200′, a first control switch 201′, a second control switch 202′, an integration capacitor 203′, and a comparator 204′ form a fixed-slope generating circuit, which is coupled to a capacitor under test 205′. Different capacitance values of the capacitor under test 205′ result in different initial voltages, and hence resulting in difference in enabling time of the comparator 204′. Thereby, the objective of sensing capacitance is achieved.

FIG. 3 shows a block diagram of another capacitance sensing apparatus according to the prior art. As shown in the figure, a plurality of buffers 300′, a frequency phase detector 301′, a control unit 302′, and a controllable buffer 303′ form a generation time-to-digital converter, which is coupled to a capacitor under test 304′. Different capacitance values of the capacitor under test 304′ result in time differences in the control signals output by the control unit 302′. Thereby, the objective of sensing capacitance is achieved.

Nevertheless, the technologies shown in FIGS. 1 to 3 lack immunity to EMI. In particular, the applications of capacitance sensing generally need to work with peripheral circuits such as microprocessors. When electromagnetic noise is coupled to the comparators via capacitors, oscillation frequencies will distort or the initial voltage will vary, and hence resulting in errors in capacitance detection. Additionally, the circuits described above need more clock cycles for detecting capacitance.

Accordingly, the present invention provides a capacitance sensing circuit with anti-EMI capability, which can prevent performance deterioration in the capacitance sensing circuit due to EMI. Hence, the problems described above can be solved.

### SUMMARY

An objective of the present invention is to provide a capacitance sensing circuit with anti-EMI capability, which uses a difference circuit to eliminate common-mode noise for achieving anti-EMI capability.

Another objective of the present invention is to provide a capacitance sensing circuit with anti-EMI capability, which adjusts the dynamic range of the output of a filter. Thereby, the capacitance sensing circuit with anti-EMI capability can achieve capacitance sensing in few clock cycles.

Still another objective if the present invention is to provide a capacitance sensing circuit with anti-EMI capability, which uses a fifth switch and a sixth switch to eliminate influences by parasitic capacitor of the capacitor under test, and hence increasing the dynamic measurement range of the capacitor under test for the capacitance sensing circuit.

The capacitance sensing circuit with anti-EMI capability according to the present invention comprises a filter and a difference circuit. The filter is coupled to a capacitor under test; receives a plurality of reference signals; and produces a first filter signal and a second filter signal. The difference circuit receives the first and second filter signals; eliminates the common-mode noise in the first and second filter signals; and produces a difference signal. The amplitude of the difference signal is related to the capacitance value of the capacitor under test. Thereby, the purpose of sensing capacitance can be achieved. In addition, by eliminating common-mode noise using the difference circuit, the anti-EMI capability can be achieved. Because the difference circuit can adjust the dynamic range of the output of the filter, the capacitance sensing circuit with anti-EMI capability can achieve capacitance sensing in few clock cycles.

### BRIEF DESCRIPTION OF THE DRAWINGS

FIG. 1 shows a block diagram of a capacitance sensing apparatus according to the prior art;

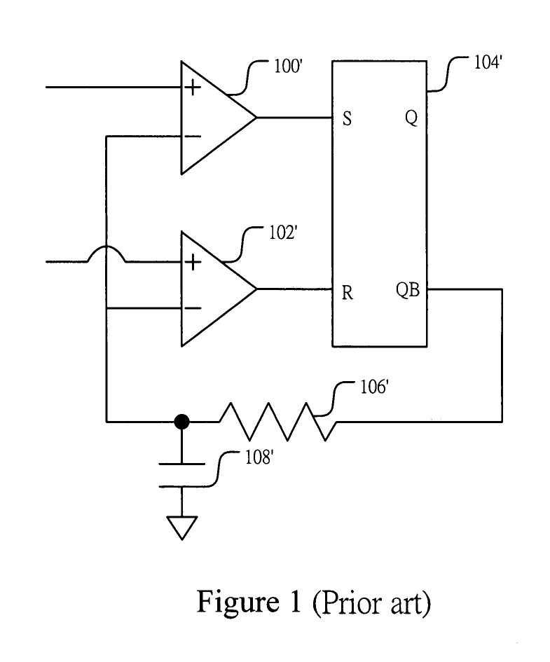

FIG. 2 shows a block diagram of another capacitance sensing apparatus according to the prior art;

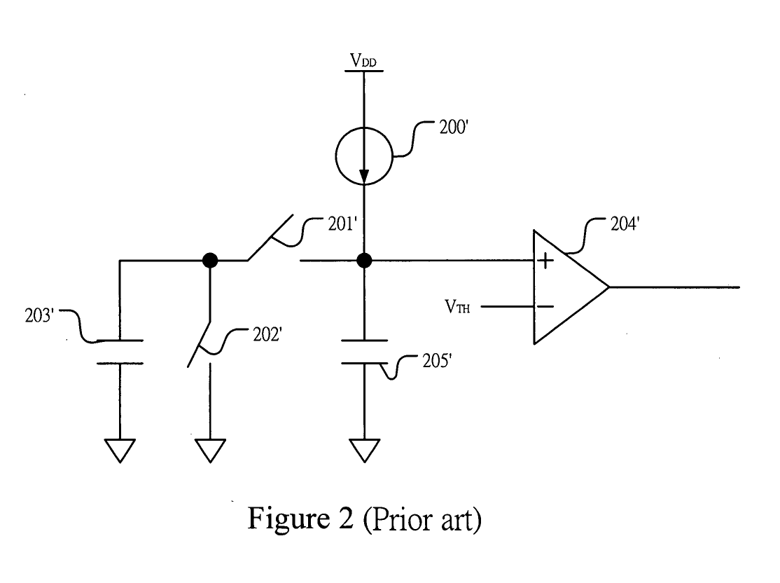

FIG. 3 shows a block diagram of another capacitance sensing apparatus according to the prior art;

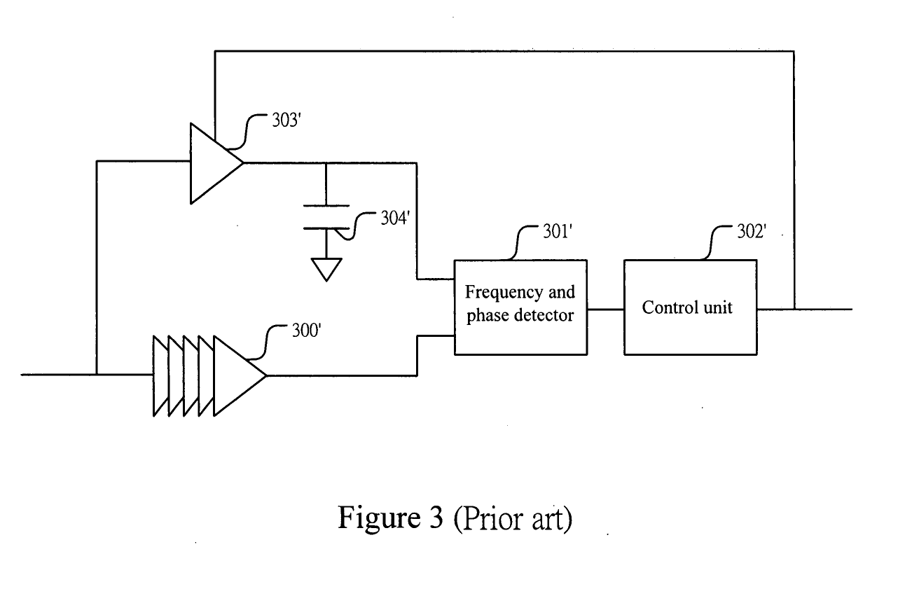

FIG. 4 shows a block diagram of a capacitance sensing circuit according to a preferred embodiment of the present invention;

FIG. 5 shows a circuit diagram of the filter shown in FIG. 4 according to a preferred embodiment of the present invention;

FIG. 6 shows output waveforms of the capacitance sensing circuit according to a preferred embodiment of the present invention;

FIG. 7A shows timing diagrams of switch control according to a preferred embodiment of the present invention;

FIG. 7B shows timing diagrams of switch control according to another preferred embodiment of the present invention;

FIG. 8 shows a circuit diagram of the filter according to another preferred embodiment of the present invention;

FIG. 9 shows a circuit diagram of the filter according to another preferred embodiment of the present invention;

FIG. 10A shows a timing diagram of the circuit diagram in FIG. 9 according to a preferred embodiment of the present invention;

FIG. 10B shows a timing diagram of the circuit diagram in FIG. 9 according to another preferred embodiment of the present invention;

FIG. 10C shows a timing diagram of the circuit diagram in FIG. 9 according to another preferred embodiment of the present invention;

FIG. 10D shows a timing diagram of the circuit diagram in FIG. 9 according to another preferred embodiment of the present invention; and

FIG. 11 shows a circuit diagram of the filter according to another preferred embodiment of the present invention.

### DETAILED DESCRIPTION

In order to make the structure and characteristics as well as the effectiveness of the present invention to be further understood and recognized, the detailed description of the present invention is provided as follows along with embodiments and accompanying figures.

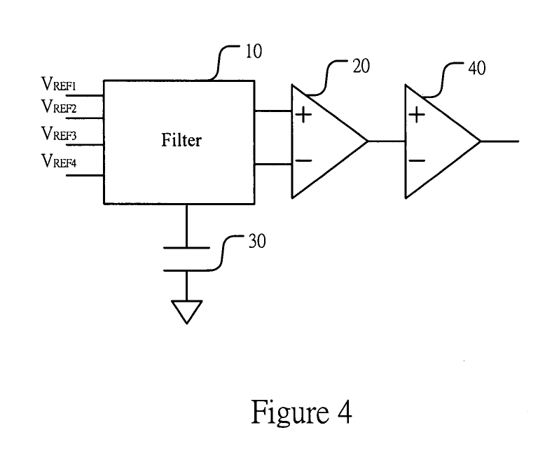

FIG. 4 shows a block diagram of a capacitance sensing circuit according to a preferred embodiment of the present invention. As shown in the figure, the capacitance sensing circuit with anti-EMI capability can be applied to fingerprint identification, accelerometers, and touch panels. The capacitance sensing circuit comprises a filter 10 and a difference circuit 20. The filter 10 is coupled to a capacitor under test 30; receives a plurality of reference signals; and produces a first filter signal and a second filter signal. Namely, the filter 10 receives a first reference signal V_{REF1}, a second reference signal V_{REF2}, a third reference signal V_{REF3}, and a fourth reference signal V_{REF4} and produces the first and second filter signals. A preferred embodiment of the filter 10 according to the present invention is a finite impulse response (FIR) filter.

The difference circuit 20 receives the first filter signal and the second filter signal; eliminates the common-mode noise of the first and second filter signals; and produces a difference signal. The amplitude of the difference signal is related to the capacitance value of the capacitor under test 30. In other words, the difference circuit 20 can calculate the difference between the first filter signal and the second filter signal, and produce the difference signal. Because the difference signal is related to the capacitor under test 30, namely, the capacitance value of the capacitor under test 30 influences the amplitude of the first and second filter signals, the amplitude of the difference signal produced by the difference circuit 20 depends on the capacitance value of the capacitor under test 30. Thereby, subsequent circuits (not shown in the figure) can deduce the capacitance value of the capacitor under test 30 according to the difference signal. Because the difference signal is given by subtracting the second filter signal from the first filter signal by the difference circuit 20, when EMI noise is produced in the first and second filter signals, the difference circuit 20 can eliminate the EMI noise by the operation of subtracting the second filter signal from the first filter signal. Hence, the common-mode noise is eliminated and the anti-EMI capability is achieved. A preferred embodiment of the difference circuit 20 according to the present invention is a difference amplifier.

In addition, the capacitance sensing circuit with anti-EMI capability according to the present invention further comprises an amplifier 40. The amplifier 40 is coupled to the difference circuit 20, and receives and amplifies the difference signal. The difference circuit 20 and the amplifier 40 thus form a dynamic-range adjustment circuit. The dynamic-range adjustment circuit can reduce the clock cycles for sensing the capacitor under test 30. Hence, power consumption can be reduced and achieving power-saving purpose. The amplifier 40 according to the present invention can be a variable gain amplifier (VGA).

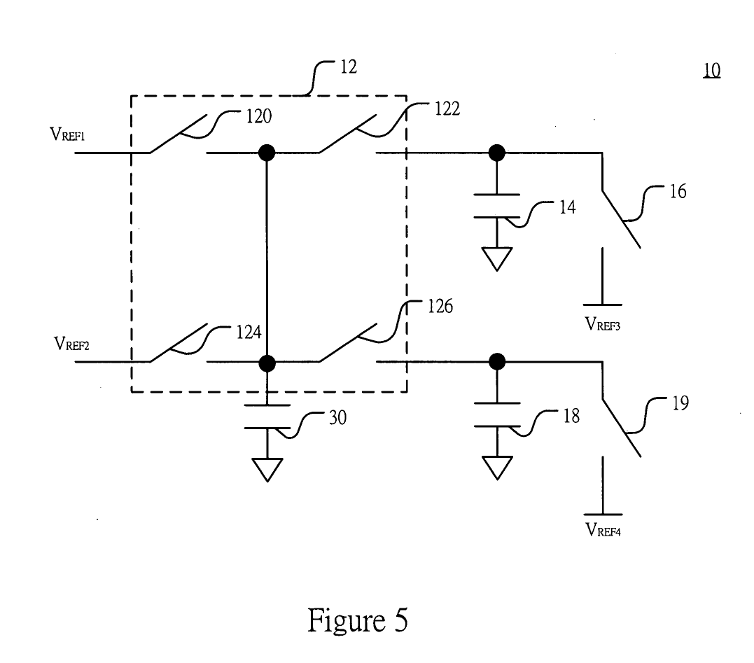

FIG. 5 shows a circuit diagram of the filter shown in FIG. 4 according to a preferred embodiment of the present invention. As shown in the figure, the filter 10 of the capacitance sensing circuit with anti-EMI capability according to the present invention comprises a switch module 12, a first output capacitor 14, a first output switch 16, a second output capacitor 18, and a second output switch 19. The switch module 12 is coupled to the capacitor under test 30 and receives the plurality of reference signals. Namely, the switch module 12 receives the first reference signal V_{REF1} and the second reference signal V_{REF2}. The first output capacitor 14 is coupled to a first output terminal of the switch module 12. The first output switch 16 is coupled between the first output capacitor 14 and the reference signal and produces the first filter signal. In other words, the first output switch 16 is coupled between the first output capacitor 14 and the third reference signal V_{REF3}, and outputs the first filter signal. The second output capacitor 18 is coupled to a second output terminal of the switch module 12. The second output switch 19 is coupled between the second output capacitor 18 and the reference signal and produces the second filter signal. In other words, the second output switch 19 is coupled between the second output capacitor 18 and the fourth reference signal V_{REF4}, and outputs the second filter signal.

Besides, the switch module 12 comprises a first switch 120, a second switch 122, a third switch 124, and a fourth switch 126. One terminal of the first switch 120 is coupled to the first reference signal V_{REF1}. The other terminal of the first switch 120 is coupled to the capacitor under test 30. One terminal of the second switch 122 is coupled to the capacitor under test 30 and the first switch 120. The other terminal of the second switch 122 is coupled to the first output capacitor 14. One terminal of the third switch 124 is coupled to the second reference signal V_{REF2}. The other terminal of the third switch 124 is coupled to the capacitor under test 30. One terminal of the fourth switch 126 is coupled to the capacitor under test 30 and the third switch 124. The other terminal of the fourth switch 126 is coupled to the second output capacitor 18. Thereby, according to the present invention, the first and second filter signals are produced by controlling the switch module 12 and the on/off sequence of the first and second output switches 16, 19.

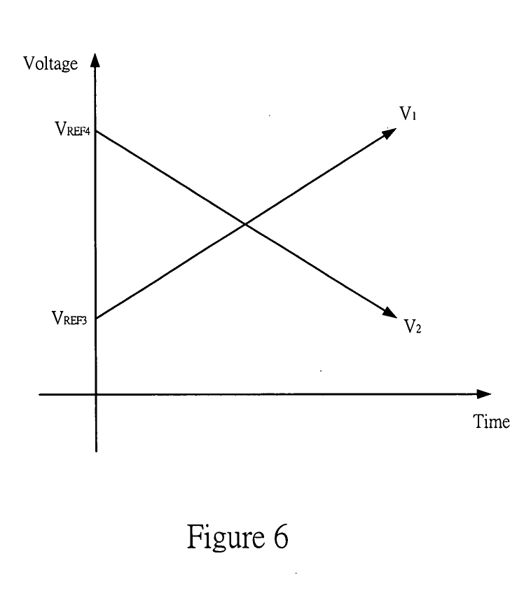

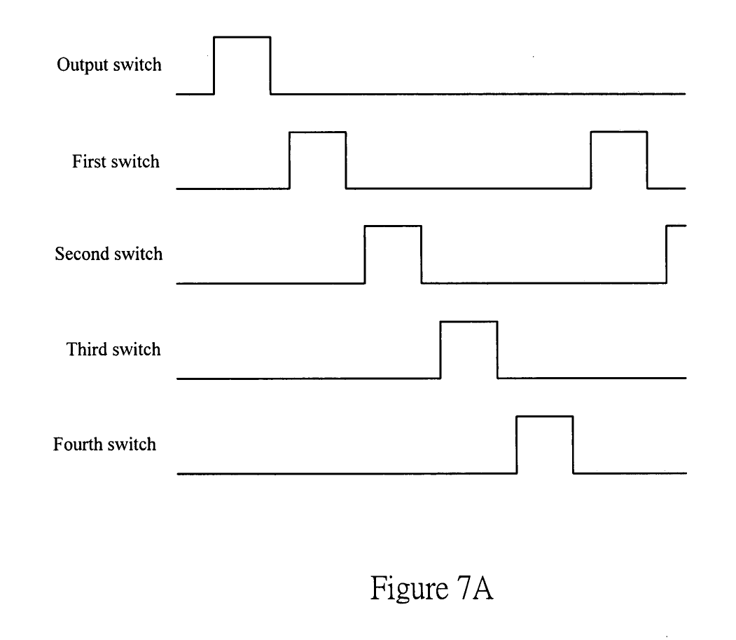

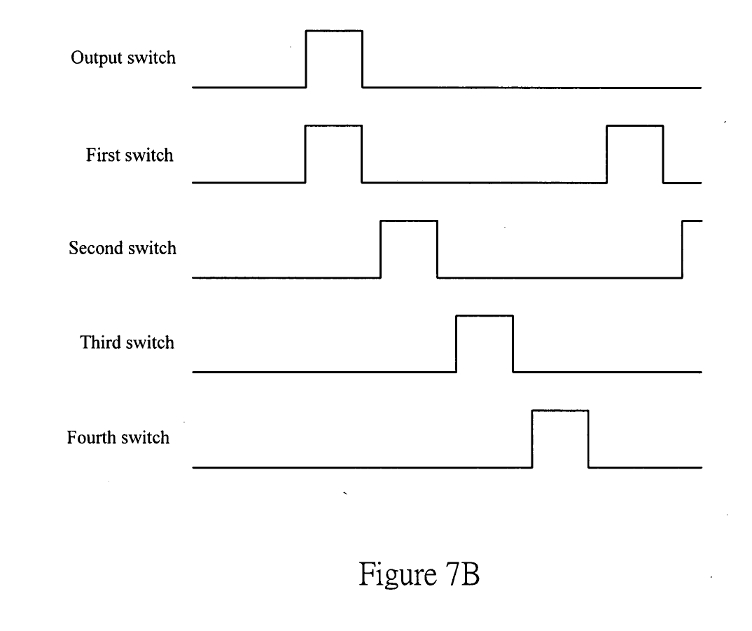

FIG. 6 and FIG. 7A show output waveforms and timing diagrams of switch control of the capacitance sensing circuit according to a preferred embodiment of the present invention. As shown in the figure, the capacitance sensing circuit according to the present invention first turns on and off the first and second output switches 16, 19. Then the first, second, third, and fourth switches 120, 122, 124, 126 are turned on and off sequentially for producing voltage variations of the first filter signal V₁ across the first output capacitor 14. The first output capacitor 14 is coupled to the third reference signal V_{REF3}. Thereby, the first filter signal V₁ varies voltage using the third reference signal V_{REF3} as an initial voltage. Likewise, voltage variations of the second filter signal V₂ are produced across the second output capacitor 18. The second output capacitor 18 is coupled to the fourth reference signal V_{REF4}. Thereby, the second filter signal V₂ varies voltage using the fourth reference signal V_{REF4} as an initial voltage. Because the voltage slope of the first filter signal V₁ and the voltage slope of the second filter signal V₂ are opposite, the difference circuit 20 can produce the difference signal according to the difference the first filter signal V₁ and the second filter signal V₂. The first output capacitor 14 and the second output capacitor 18 are integration capacitors.

Reference is made to FIG. 5 and FIG. 7A again. If an EMI signal enters the capacitor under test 30, by making the switching frequency greater than the frequency of the EMI signal, the EMI signal will be stored in the capacitor under test 30 after the first switch 120 is turned on. When the second switch 122 is turned on, the terminal of the first output capacitor 14 will give the difference of EMI signal between the first switch 120 and the second switch 122. Because the switching frequency is greater than the frequency of the EMI signal, the difference is almost equal to the slope of the EMI signal. In addition, when the third switch 124 is turned on, the terminal of the second output capacitor 18 will give the difference of EMI signal between the third switch 124 and the fourth switch 126. Because the switching frequency is greater than the frequency of the EMI signal, the difference is almost equal to the slope of the EMI signal. By using the difference circuit 20, the slope of the common-mode noise in the two EMI signals can be eliminated.

FIG. 7B shows timing diagrams of switch control according to another preferred embodiment of the present invention. As shown in the figure, the difference between the present preferred embodiment and the one in FIG. 7A is that, according to the present preferred embodiment, the first output switch 14, the second output switch 19, and the first switch 120 are turned on and off simultaneously. Then the second switch 122, the third switch 124, and the fourth switch 126 are turned on and off sequentially. Thereby, the filter according to the present preferred embodiment can also produce the waveforms as shown in FIG. 6.

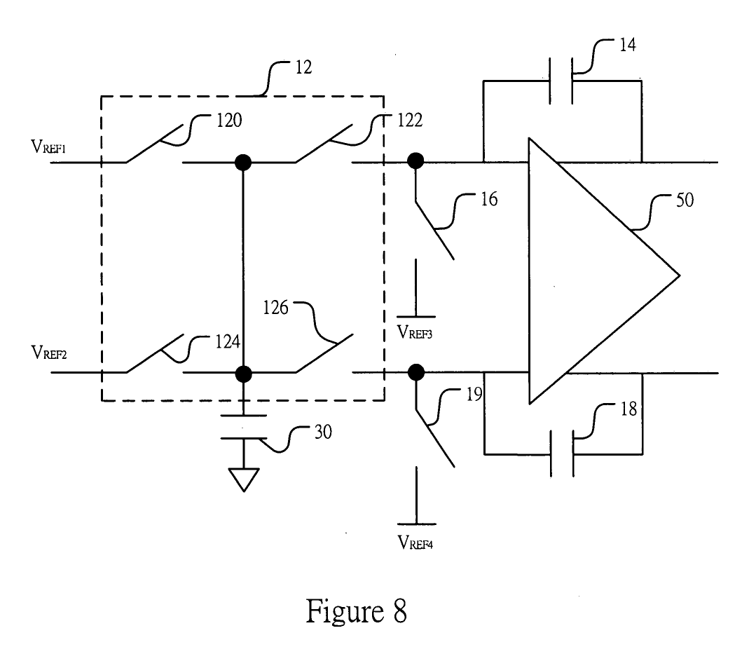

FIG. 8 shows a circuit diagram of the filter according to another preferred embodiment of the present invention. As shown in the figure, the difference between the present preferred embodiment and the one in FIG. 5 is that the present preferred embodiment further comprises an amplifier 50. The amplifier 50 has a first input terminal, a second input terminal, a first output terminal, and a second output terminal. The first and second input terminals are coupled to the switch module 12. The first and second output terminals are used for outputting the first filter signal and the second filter signal. The first output capacitor 14 is coupled between the first input terminal and the first output terminal of the amplifier 50. The second output capacitor 18 is coupled between the second input terminal and the second output terminal. One terminal of the first output switch 16 is coupled to the switch module 12 and the amplifier 50. The other terminal of the first output switch 16 is coupled to the third reference signal V_{REF3}. One terminal of the second output switch 19 is coupled to the switch module 12 and the amplifier 50. The other terminal of the second output switch 19 is coupled to the reference signal V_{REF4}. The amplifier 50 is added for increasing voltage gain, and thus increasing amplification of the first and second filter signals. Thereby, the first and second output capacitors 14, 18 with smaller capacitance values can be used, and hence saving costs. A preferred embodiment of the amplifier 50 according to the present invention is an operational amplifier (OPA).

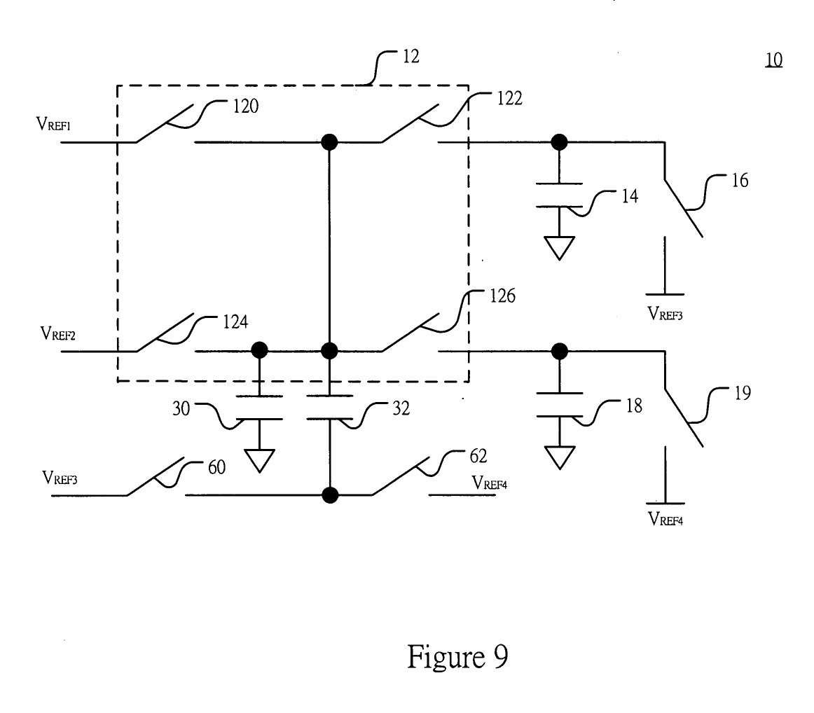

FIG. 9 shows a circuit diagram of the filter according to another preferred embodiment of the present invention. As shown in the figure, because the capacitor under test 30 produces a parasitic capacitor 32 coupled to a terminal of the capacitor under test 30 as well as to the switch module 12. Because of the parasitic capacitor 32, the dynamic range of the capacitance sensing circuit while measuring the capacitor under test 30 will be too small. Thereby, the filter 10 in the capacitance sensing circuit according to the present embodiment of the present invention further comprises a fifth switch 60 and a sixth switch 62. A terminal of the fifth switch 60 is coupled to the reference signal, namely, the third reference signal V_{REF3}; the other terminal of the fifth switch 60 is coupled to the parasitic capacitor 32. A terminal of the sixth switch 62 is coupled to the fifth switch 60 and the parasitic capacitor 32; the other terminal of the sixth switch 62 is coupled to the reference signal, namely, the fourth reference signal V_{REF4}. Hence, by coordinating the turn-on sequence of the first switch 120 to the fourth switch 126 of the switch module 12, the dynamic measurement range for the capacitor under test 30 according to the present embodiment is increased. In the following, how the fifth and the sixth switches 60, 62 work with the turn-on sequence of the first switch 120 to the fourth switch 126 of the switch module 12 will be described.

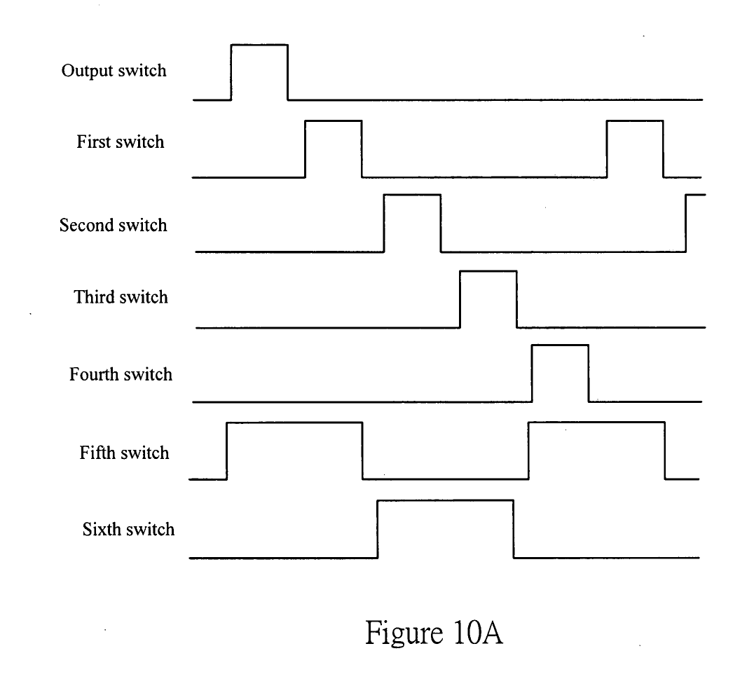

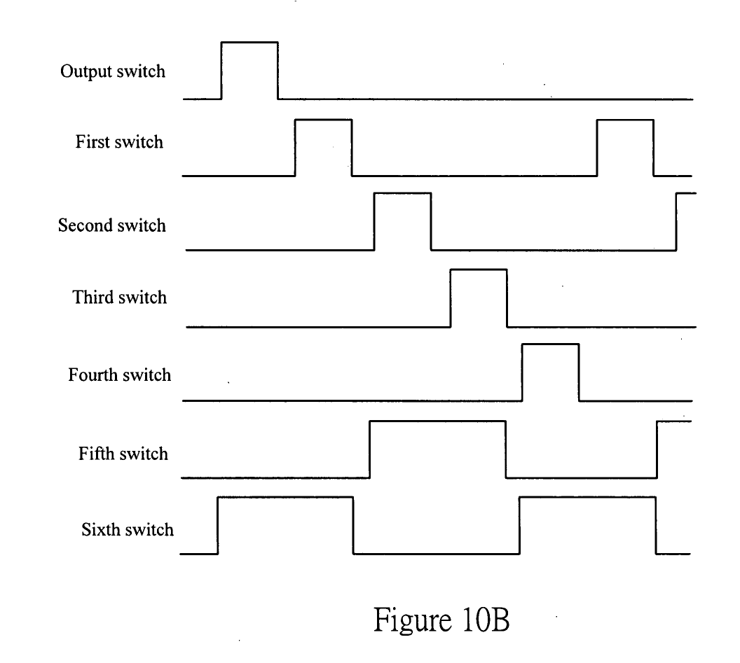

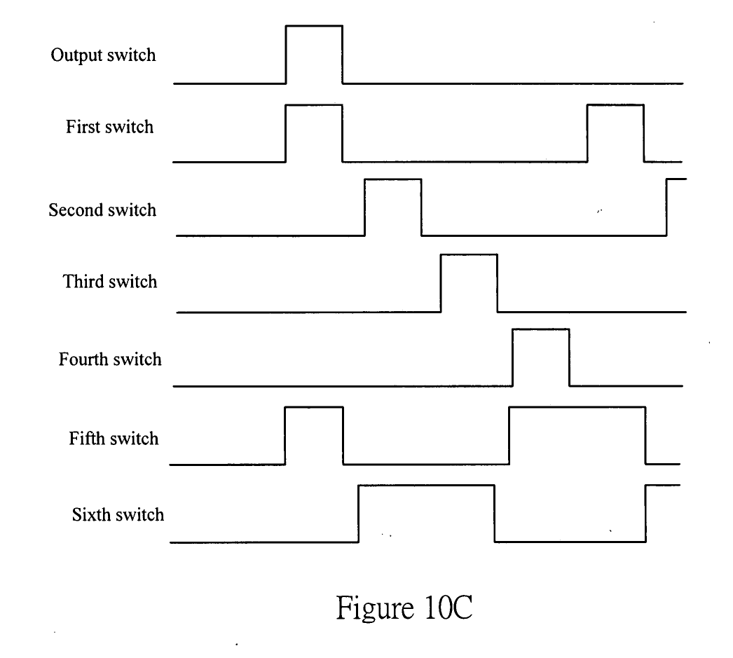

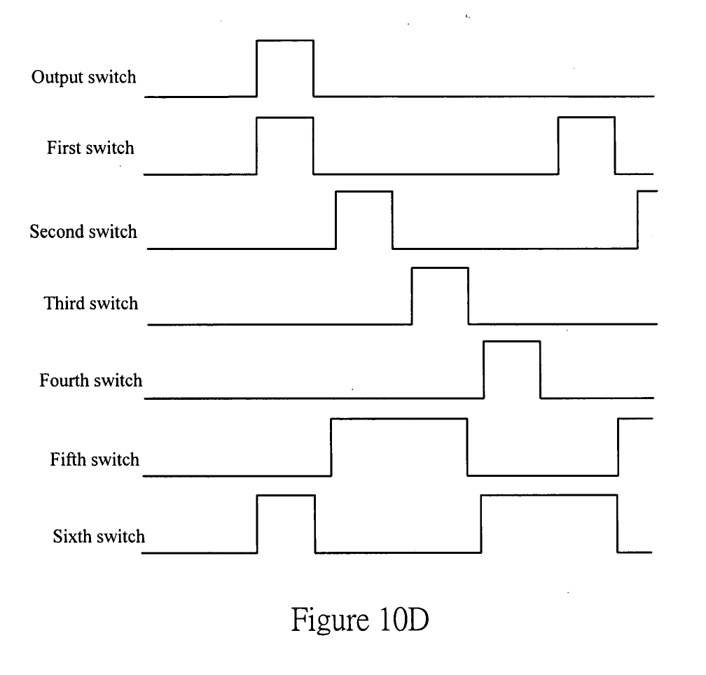

FIG. 10A shows a timing diagram of the circuit diagram in FIG. 9 according to a preferred embodiment of the present invention. As shown in the figure, when the first output switch 16 and the second output switch 19 are turned on, the fifth switch 60 is also turned on. The first switch 120 is turned on right after the first output switch 16 and the second output switch 19 are turned on; the fifth switch 60 is turned off simultaneously when the first switch 120 is turned off. At this moment, the second switch 122 and the sixth switch 62 are turned on. Then the third switch 124 is turned on subsequently. When the third switch 124 is turned off, the sixth switch 62 is also turned off. Afterwards, the fourth switch 126 and the fifth switch 60 are turned on. By repeating the on/off sequence as described above, the influence of the capacitance of the parasitic capacitor 32 on the capacitance of the capacitor under test 30 is relatively reduced, and hence increasing the dynamic measurement range of the capacitor under test 30. According to the sequence of the above switches, it is known that the voltage across the first output capacitor 14 is:

$${V}_{{C}_{14}} = \frac{{C}_{30}}{{C}_{14} + {C}_{32} + {C}_{30}} [ \begin{matrix}1 + ( \frac{{C}_{30}}{{C}_{14} + {C}_{32} + {C}_{30}} ) + \\ {( \frac{{C}_{30}}{{C}_{14} + {C}_{32} + {C}_{30}} )}^{2} + … + \\ {( \frac{{C}_{30}}{{C}_{14} + {C}_{32} + {C}_{30}} )}^{n}\end{matrix} ] * V D D \qquad ( 1 )$$

If n approaches infinity,

$${V}_{{C}_{14}} = \frac{{C}_{30}}{{C}_{30} + {C}_{32}} * V D D \qquad ( 2 )$$

According to the above, when the capacitance of the capacitor under test 30 is far greater than that of the parasitic capacitor 32, the latter can be ignored and hence increasing the dynamic measurement range of the capacitor under test 30. According to the present embodiment, the early simultaneous occurrence of V_{C14} and V_{C18} is prevented for not influencing the dynamic measurement range of the capacitor under test 30. Likewise, the voltage across the second output capacitor 18 can be deduced according to the above-mentioned method. Moreover, in FIG. 10C, the on/off sequence of the first switch 120 to the sixth switch 62 is approximately the same as the one in FIG. 10A except that when the first output switch 16 and the second output switch 19 are turned on, the first switch 120 and the fifth switch 60 are also turned on in FIG. 10C. The rest of the sequence is the same as in FIG. 10A, and thereby will not be described again.

FIG. 10B shows a timing diagram of the circuit diagram in FIG. 9 according to another preferred embodiment of the present invention. As shown in the figure, the difference between the present embodiment and the one in FIG. 10A is that, according to the present embodiment, when the first output switch 16 and the second output switch 19 are turned on, the sixth switch 62 is also turned on. The first switch 120 is turned on right after the first output switch 16 and the second output switch 19 are turned on; the sixth switch 62 is turned off simultaneously when the first switch 120 is turned off. At this moment, the second switch 122 and the fifth switch 60 are turned on. Then the third switch 124 is turned on subsequently. When the third switch 124 is turned off, the fifth switch 60 is also turned off. Afterwards, the fourth switch 126 and the sixth switch 62 are turned on. By repeating the on/off sequence as described above, the influence of the capacitance of the parasitic capacitor 32 on the capacitance of the capacitor under test 30 is relatively increased. Then the capacitance of the capacitor under test 30 is given by means of knowing the capacitance of the parasitic capacitance 32, and hence increasing the dynamic measurement range of the capacitor under test 30. According to the sequence of the above switches, it is known that the voltage across the first output capacitor 14 is:

$${V}_{{C}_{14}} = \frac{{C}_{30} + 2 {C}_{32}}{{C}_{14} + {C}_{32} + {C}_{30}} [ \begin{matrix}1 + ( \frac{{C}_{30}}{{C}_{14} + {C}_{32} + {C}_{30}} ) + \\ {( \frac{{C}_{30}}{{C}_{14} + {C}_{32} + {C}_{30}} )}^{2} + … + \\ {( \frac{{C}_{30}}{{C}_{14} + {C}_{32} + {C}_{30}} )}^{n}\end{matrix} ] * V D D \qquad ( 3 )$$

If n approaches infinity,

$${V}_{{C}_{14}} = \frac{{C}_{30} + 2 {C}_{32}}{{C}_{30} + {C}_{32}} * V D D \qquad ( 4 )$$

According to the above, when the capacitance of the parasitic capacitor 32 is far greater than that of the capacitor under test 30, the capacitance of the capacitor under test 30 is deduced by means of the capacitance of the parasitic capacitor 32, and hence increasing the dynamic measurement range of the capacitor under test 30. According to the present embodiment, the late simultaneous occurrence of V_{C14} and V_{C18} is prevented for not influencing the dynamic measurement range of the capacitor under test 30. Likewise, the voltage across the second output capacitor 18 can be deduced according to the above-mentioned method. Moreover, in FIG. 10D, the on/off sequence of the first switch 120 to the sixth switch 62 is approximately the same as the one in FIG. 10B except that when the first output switch 16 and the second output switch 19 are turned on, the first switch 120 and the sixth switch 62 are also turned on in FIG. 10C. The rest of the sequence is the same as in FIG. 10B, and thereby will not be described again.

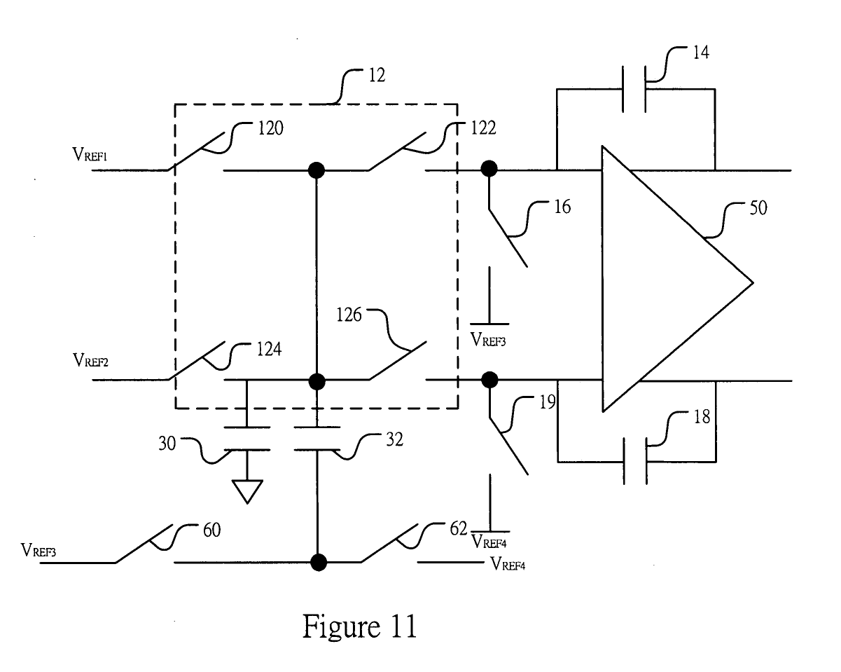

FIG. 11 shows a circuit diagram of the filter according to another preferred embodiment of the present invention. As shown in the figure, the difference between the present embodiment and the one in FIG. 9 is that the present embodiment further comprises an amplifier 50. The amplifier 50 has a first input terminal, a second input terminal, a first output terminal, and a second output terminal. The first and second input terminals are coupled to the switch module 12. The first and second output terminals are used for outputting the first filter signal and the second filter signal. The first output capacitor 14 is coupled between the first input terminal and the first output terminal of the amplifier 50. The second output capacitor 18 is coupled between the second input terminal and the second output terminal. One terminal of the first output switch 16 is coupled to the switch module 12 and the amplifier 50. The other terminal of the first output switch 16 is coupled to the third reference signal V_{REF3}. One terminal of the second output switch 19 is coupled to the switch module 12 and the amplifier 50. The other terminal of the second output switch 19 is coupled to the reference signal V_{REF4}. The amplifier 50 is added for increasing voltage gain, and thus increasing amplification of the first and second filter signals. Thereby, the first and second output capacitors 14, 18 with smaller capacitance values can be used, and hence saving costs. The rest structure is the same as in FIG. 9, and thereby will not be described in more detail.

To sum up, the capacitance sensing circuit with anti-EMI capability according to the present invention comprises a filter and a difference circuit. The filter is coupled to a capacitor under test; receives a plurality of reference signals; and produces a first filter signal and a second filter signal. The difference circuit receives the first and second filter signals; eliminates the common-mode noise in the first and second filter signals; and produces a difference signal. The amplitude of the difference signal is related to the capacitance value of the capacitor under test. Thereby, the purpose of sensing capacitance can be achieved. In addition, by eliminating common-mode noise using the difference circuit, the anti-EMI capability can be achieved. Because the difference circuit can adjust the dynamic range of the output of the filter, the capacitance sensing circuit with anti-EMI capability can achieve capacitance sensing in few clock cycles.

Accordingly, the present invention conforms to the legal requirements owing to its novelty, nonobviousness, and utility. However, the foregoing description is only embodiments of the present invention, not used to limit the scope and range of the present invention. Those equivalent changes or modifications made according to the shape, structure, feature, or spirit described in the claims of the present invention are included in the appended claims of the present invention.

1. A capacitance sensing circuit with anti-electromagnetic interference capability, comprising:
a filter, coupled to a capacitor under test, receiving a plurality of reference signals, and producing a first filter signal and a second filter signal; and
a difference circuit, receiving said first filter signal and said second filter signal, eliminating the common-mode noise in said first filter signal and said second filter signal, producing a difference signal with an amplitude related to the capacitance of said capacitor under test.

2. The capacitance sensing circuit with anti-electromagnetic interference capability of claim 1, and further comprising an amplifier, receiving and amplifying said difference signal.

3. The capacitance sensing circuit with anti-electromagnetic interference capability of claim 2, wherein said amplifier is a variable gain amplifier.

4. The capacitance sensing circuit with anti-electromagnetic interference capability of claim 1, wherein said filter comprises:
a switch module, coupled to said capacitor under test, and receiving said plurality of reference signals;
a first output capacitor, coupled to a first output terminal of said switch module;
a first output switch, coupled between said first output capacitor and said reference signal, and producing said first filter signal;
a second output capacitor, coupled to a second output terminal of said switch module; and
a second output switch, coupled between said second output capacitor and said reference signal, and producing said second filter signal.

5. The capacitance sensing circuit with anti-electromagnetic interference capability of claim 4, wherein said switch module comprises:
a first switch, with one terminal coupled to said reference signal, and the other terminal coupled to said capacitor under test;
a second switch, with one terminal coupled to said capacitor under test and said first switch, and the other terminal coupled to said first output capacitor;
a third switch, with one terminal coupled to said reference signal, and the other terminal coupled to said capacitor under test; and
a fourth switch, with one terminal coupled to said capacitor under test and said third switch, and the other terminal coupled to said second output capacitor.

6. The capacitance sensing circuit with anti-electromagnetic interference capability of claim 5, wherein said first output capacitor and said output capacitor are integration capacitors.

7. The capacitance sensing circuit with anti-electromagnetic interference capability of claim 1, wherein said filter comprises:
a switch module, coupled to said capacitor under test, and receiving said plurality of reference signals;
an amplifier, having a first input terminal, a second input terminal, a first output terminal, and a second output terminal, said first input terminal and said second input terminal coupled to said switch module, and said first output terminal and said second output terminal used for outputting said first filter signal and said second filter signal;
a first output capacitor, coupled between said first input terminal and said first output terminal of said amplifier;
a second output capacitor, coupled between said second input terminal and said second output terminal of said amplifier;
a first output switch, with one terminal coupled to said switch module and said amplifier, and the other terminal coupled to said reference signal; and
a second output switch, with one terminal coupled to said switch module and said amplifier, and the other terminal coupled to said reference signal.

8. The capacitance sensing circuit with anti-electromagnetic interference capability of claim 7, wherein said switch module comprises:
a first switch, with one terminal coupled to said reference signal, and the other terminal coupled to said capacitor under test;
a second switch, with one terminal coupled to said capacitor under test and said first switch, and the other terminal coupled to said first output capacitor and said amplifier;
a third switch, with one terminal coupled to said reference signal, and the other terminal coupled to said capacitor under test; and
a fourth switch, with one terminal coupled to said capacitor under test and said third switch, and the other terminal coupled to said second output capacitor and said amplifier.

9. The capacitance sensing circuit with anti-electromagnetic interference capability of claim 7, wherein said amplifier is an operational amplifier.

10. The capacitance sensing circuit with anti-electromagnetic interference capability of claim 7, wherein said first output capacitor and said second output capacitor are integration capacitors.

11. The capacitance sensing circuit with anti-electromagnetic interference capability of claim 1, wherein said difference circuit is a difference amplifier.

12. The capacitance sensing circuit with anti-electromagnetic interference capability of claim 1, wherein said filter is a finite impulse response filter.

13. The capacitance sensing circuit with anti-electromagnetic interference capability of claim 1, and applied to fingerprint identification, accelerometers, and touch panels.

14. The capacitance sensing circuit with anti-electromagnetic interference capability of claim 4, wherein said capacitor under test further includes a parasitic capacitor coupled to a terminal of said capacitor under test and to said switch module.

15. The capacitance sensing circuit with anti-electromagnetic interference capability of claim 14, wherein said filter further comprises:
a fifth switch, with one terminal coupled to said reference signal, and the other terminal coupled to said parasitic capacitor; and
a sixth switch, with one terminal coupled to said fifth switch and said parasitic capacitor, and the other terminal coupled to said reference signal.

16. The capacitance sensing circuit with anti-electromagnetic interference capability of claim 7, wherein said capacitor under test further includes a parasitic capacitor coupled to a terminal of said capacitor under test and to said switch module.

17. The capacitance sensing circuit with anti-electromagnetic interference capability of claim 16, wherein said filter further comprises:
a fifth switch, with one terminal coupled to said reference signal, and the other terminal coupled to said parasitic capacitor; and
a sixth switch, with one terminal coupled to said fifth switch and said parasitic capacitor, and the other terminal coupled to said reference signal.
